(19) United States
(12) Patent Application Publication
(10) Pub. No.: US 2010/0127354 A1
(43) Pub. Date: May 27, 2010

(54) SILICON SINGLE CRYSTAL AND METHOD FOR GROWING THEREOF, AND SILICON WAFER AND METHOD FOR MANUFACTURING THEREOF

(75) Inventors: Toshiaki ONO, Tokyo (JP); Toshiyuki FUJIWARA, Tokyo (JP); Masataka HOURAI, Tokyo (JP); Wataru SUGIMURA, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/625,691

(22) Filed: Nov. 25, 2009

(30) Foreign Application Priority Data
Nov. 27, 2008 (JP) 2008-303049

(51) Int. Cl. H01L 29/12; H01L 21/20; C30B 15/14; C01B 33/02

(52) U.S. Cl. 257/618; 438/509; 117/3; 423/348; 257/E21.09; 257/E29.068

(57) ABSTRACT

A method for growing a silicon single crystal having a hydrogen defect density of equal to or less than 0.003 pieces/cm² using a Czochralski method, includes: a crystal growth step performed in an atmospheric gas containing a hydrogen-containing gas so as to allow hydrogen gas to have a partial pressure of equal to or higher than 40 Pa and equal to or lower than 400 Pa; and a cooling state control step of setting the amount of time in a hydrogen aggregation temperature range which is a range of equal to or lower than 850° C. and equal to or higher than 550° C. to be equal to or longer than 100 minutes and equal to or shorter than 480 minutes.

### BACKGROUND OF THE INVENTION

1. Field of the Invention

The present invention relates to a silicon single crystal and a method for growing thereof, and a silicon wafer and a method for manufacturing thereof, and more particularly, to a technique suitable for preventing the generation of hydrogen defects upon pulling a silicon single crystal using hydrogen doping.

Priority is claimed on Japanese Patent Application No. 2008-303049, filed on Nov. 27, 2008, the content of which is incorporated herein by reference.

2. Description of Related Art

The inventors described a method for growing a silicon single crystal in Japanese Unexamined Patent Application, First publication No. 2007-22863. In the method for growing a silicon single crystal, even though atmospheric gas in which a single crystal is grown includes gas of materials containing hydrogen atoms, it is possible to grow the silicon single crystal at a pulling speed equal to or higher than a threshold pulling speed at which an OSF generating region is generated. Therefore, it is possible to grow a silicon single crystal including OSF generating regions without hydrogen defects.

However, it was found using a device that can measure minute defects that at low density hydrogen defects occur even under the condition disclosed in Japanese Unexamined Patent Application, First publication No. 2007-22863.

### SUMMARY OF THE INVENTION

The present invention is designed to solve the above-mentioned problems. An object of the present invention is to enable the manufacturing of a more perfect defect-free crystal by suppressing the generation of hydrogen defects while maintaining high controllability of V/G by pulling a single crystal in a hydrogen atmosphere.

According to the present invention, there is provided a method for growing a silicon single crystal having a hydrogen defect density of equal to or less than 0.003 pieces/cm² using a Czochralski method. The method for growing a silicon single crystal comprises a crystal growth step of growing the silicon single crystal in an atmospheric gas containing a hydrogen-containing gas (a gas of a hydrogen-containing material) so as to allow the reduced hydrogen partial pressure gas to be equal to or higher than 40 Pa and equal to or lower than 400 Pa, and a cooling state control step of keeping the silicon single crystal in a hydrogen aggregation temperature range which is a range of equal to or lower than 850° C. and equal to or higher than 550° C. to be equal to or longer than 100 minutes and equal to or shorter than 480 minutes.

In the method according to the present invention, in the crystal growth step, preferably, the silicon single crystal is pulled in a range from a pulling speed at which the ratio (a/b) of the outside diameter (a) of a ring composed of an OSF generating region in a radial direction of the silicon single crystal to the diameter (b) of the silicon single crystal is equal to or lower than 0.55 to a pulling speed at which the OSF generating ends at the center portion of the crystal.

In the method for growing a silicon single crystal according to the present invention, it is possible to pull the silicon single crystal in which an area outside the ring is a defect-free region.

In the method according to the present invention, in the crystal growth step, the silicon single crystal may be pulled in a range from a pulling speed at which, in the cross-section of the silicon single crystal in the radial direction, the ratio (c/d) of a wafer area (c) of the silicon single crystal composed of a dislocation cluster generating region to the area (d) of the silicon single crystal is equal to or lower than 0.15 to a pulling speed at which the dislocation cluster generating region is excluded from the entire wafer surface.

According to the present invention, a method of pulling the silicon single crystal in which an area inside the dislocation cluster generating region is a defect-free region may be employed.

In the method for growing a silicon single crystal according to the present invention, preferably, the silicon single crystal is grown by using a hot zone structure in which a temperature gradient (Gc) at the center portion of the crystal is equal to or greater than a temperature gradient (Ge) at the peripheral portion of the crystal (Gc≧Ge).

In the method for growing a silicon single crystal according to the present invention, it is possible to grow a silicon single crystal having an oxygen concentration of equal to or less than 12×10¹⁷ atoms/cm³ (Old-ASTM).

In the method for growing a silicon single crystal according to the present invention, the gas of the hydrogen-containing material may be hydrogen gas.

A silicon single crystal is preferably grown by any one of the methods for growing a silicon single crystal described above.

According to the present invention, there is provided a method for manufacturing a silicon wafer, which further comprises, acquiring a silicon wafer from a straight portion of the silicon single crystal obtained by the method for growing a silicon single crystal according to the present invention, wherein the silicon wafer has a hydrogen defect density of equal to or less than 0.003 pieces/cm².

The method for manufacturing a silicon wafer according to the present invention, further comprises, growing an epitaxial layer on the surface of the silicon wafer, or performing a heat treatment for forming a defect-free layer on the silicon wafer.

According to the present invention, there is provided a silicon wafer manufactured by any one of the manufacturing method described above.

The method for growing a silicon single crystal according to the present invention is a method for growing a silicon single crystal having a hydrogen defect density of equal to or less than 0.003 pieces/cm² using a Czochralski method. The method for growing a silicon single crystal according to the present invention includes, a crystal growth step of growing the silicon single crystal in an atmospheric gas containing a hydrogen-containing gas so as to allow the reduced hydrogen partial pressure gas to be equal to or higher than 40 Pa and equal to or lower than 400 Pa, and a cooling state control step of keeping the silicon single crystal in a hydrogen aggregation temperature range which is a range of equal to or lower than 850° C. and equal to or higher than 550° C. to be equal to or longer than 100 minutes and equal to or shorter than 480 minutes. According to the method described above, it is possible to simultaneously realize a desirable increase in V/G range upon pulling in a hydrogen gas atmosphere (hydrogen doping) and a reduction in generation of hydrogen defects, which could not be realized in the past.

### BRIEF DESCRIPTION OF THE DRAWINGS

FIG. 1 is a cross-sectional view for explaining a defect distribution state of a silicon wafer or a silicon single crystal obtained using a CZ method in a radial direction.

FIG. 2 is a cross-sectional view for explaining a defect distribution state of a silicon single crystal grown by slowly reducing a pulling speed upon pulling.

FIG. 3 is a cross-sectional view for explaining a defect distribution state of a silicon single crystal grown by slowly reducing a pulling speed upon pulling by using a growth apparatus having a hot zone structure in which a temperature gradient (Gc) at the center portion of a crystal is equal to or greater than a temperature gradient (Ge) at the peripheral portion of the crystal (Gc≧Ge).

FIG. 4 is a cross-sectional view for explaining a defect distribution state of a silicon single crystal grown by slowly reducing a pulling speed upon pulling by supplying an inert gas to which hydrogen is added to a pulling furnace using a growth apparatus having the same hot zone structure (Gc≧Ge) as that of FIG. 3.

FIG. 5 is a graph showing a relationship between hydrogen partial pressure in an atmosphere and V/G.

FIG. 6 is a longitudinal cross-sectional view of a CZ furnace suitable for performing the method for growing a silicon single crystal according to the present invention.

FIG. 7 is a graph for explaining how a relationship between an OSF ring position in a radial direction and a vacancy concentration distribution changes with the generation of hydrogen defects.

FIG. 8 is a graph for explaining how a relationship between an OSF ring position in a radial direction and a vacancy concentration distribution changes with the generation of hydrogen defects.

FIG. 9 is a graph for explaining how a relationship between an OSF ring position in a radial direction and a vacancy concentration distribution changes with the generation of hydrogen defects.

FIG. 10 is a diagram showing a relationship between V/G and regions.

FIG. 11 is a graph showing a relationship between the hydrogen defects density and a cooling temperature in a separation cooling experiment to show a temperature range in which hydrogen defects are formed.

FIG. 12 is a graph showing a relationship between the rotation frequency of a vitreous silica crucible, the rotation frequency of a crystal, and an interstitial oxygen concentration.

FIG. 13 is a graph showing a relationship between a crystallization temperature and a stay time in a cooling process.

### DETAILED DESCRIPTION OF THE INVENTION

The inventors examined the pulling of a silicon single crystal by trial and error, and acquired knowledge of hydrogen defects as follows.

A mechanism of generating hydrogen defects is considered as follows.

When a silicon single crystal is pulled, an atmospheric gas containing hydrogen is used to dope the silicon single crystal with hydrogen through a raw material melt. As the crystal is pulled, the single crystal is cooled from a silicon melting point.

Hydrogen that becomes oversaturated after the single crystal is cooled is gathered in COP (Crystal Originated Particle) which is an aggregate of point defects or a dislocation cluster which is an aggregate of interstitial silicon, that is, grown-in defects thereof.

Here, since COP is a void, that is, a vacancy, the gathered hydrogen atoms are gasified to form a thin H₂ gas aggregate. It is considered that this is because when hydrogen (H) is gathered in COP, it would be better for the hydrogen to be bonded to become gas of the H₂ for stabilization.

As a result, the hydrogen gas H₂ has pressure (partial pressure) that seems to press the crystal outwardly from the inside of the void. Due to the pressure, cracks may be generated in the crystal structure from the pressed COP, and may extend in the <110> direction and form a large hydrogen defect.

Further, the inventors have found that a temperature range that causes the aggregation of hydrogen is a range of equal to or higher than about 600° C. and equal to or lower than about 700° C. as in an embodiment described later. That is, they invented a rapid reduction in the temperature zone (hydrogen aggregation temperature range) of equal to or higher than about 600° C. and equal to or lower than about 700° C. Specifically, they attained the knowledge that by reducing the time it takes to pass through the hydrogen aggregation temperature range during the cooling of the crystal as much as possible, it is possible to reduce the aggregation of hydrogen in defects inside the single crystal, and to reduce the partial pressure of the aggregated hydrogen gas, which is generated in the void and exerted outward, thereby suppressing the generation of hydrogen defects that are grown by the cracks generated from the void.

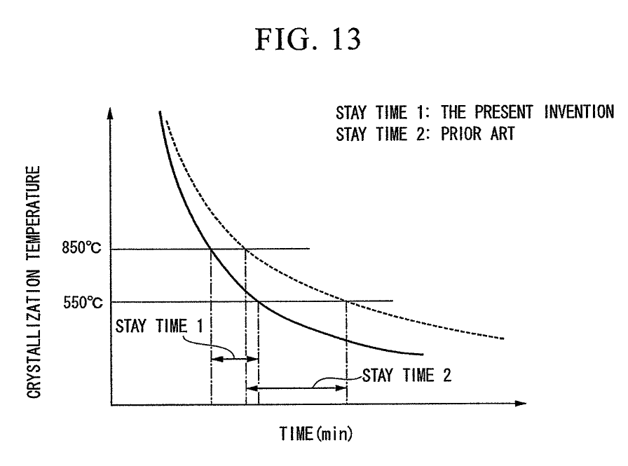

Additionally, more specifically, according to the present invention, as shown in FIG. 13, the amount of the time in the hydrogen aggregation temperature range in which the crystallization temperature of the single crystal under pulling is in the range of from 850° C. to 550° C. is set to be equal to or longer than about 100 minutes and equal to or shorter than about 480 minutes. Specifically, as compared with the stay time in the prior art shown as a stay time 2 in FIG. 13 which is equal to or longer than 500 minutes and equal to or shorter than 750 minutes, the stay time is set to be equal to or longer than 100 minutes and equal to or shorter than 480 minutes as shown as a stay time 1 in FIG. 13 for the pulling. As such, it is possible to prevent the generation of a gas internal pressure due to hydrogen gathered in the void and the generation of hydrogen defects due to the gas pressure by reducing the stay time.

More preferably, the amount of the time in the hydrogen aggregation temperature range in which the crystallization temperature of the single crystal under pulling is in the range of 800 to 600° C. is set to be equal to or longer than 100 minutes and equal to or shorter than 400 minutes.

In addition, it was determined by the inventors that when a silicon single crystal is grown by a Czochralski method, it is possible to reduce the generation of hydrogen defects in a defect-free region under the conditions below; however, the generation of hydrogen defects is not completely prevented in a boundary region between the defect-free region and other regions. The conditions are to include a gas of a hydrogen-containing material in an atmospheric gas for growing a single crystal to allow a reduced hydrogen partial pressure gas to be equal to or higher than 40 Pa and equal to or lower than 400 Pa, and to perform pulling of a silicon single crystal at from a pulling speed at which the ratio (a/b) of the outside diameter (a) of a ring composed of an OSF generating region in a radial direction of the silicon single crystal to the diameter (b) of the silicon single crystal is equal to or lower than 0.77 to a pulling speed at which the OSF generating ends at the center portion of the crystal.

That is, in a growth method using the Czochralski method (hereinafter, referred to as CZ method), hydrogen defects occur depending on a V/G value even in the defect-free region.

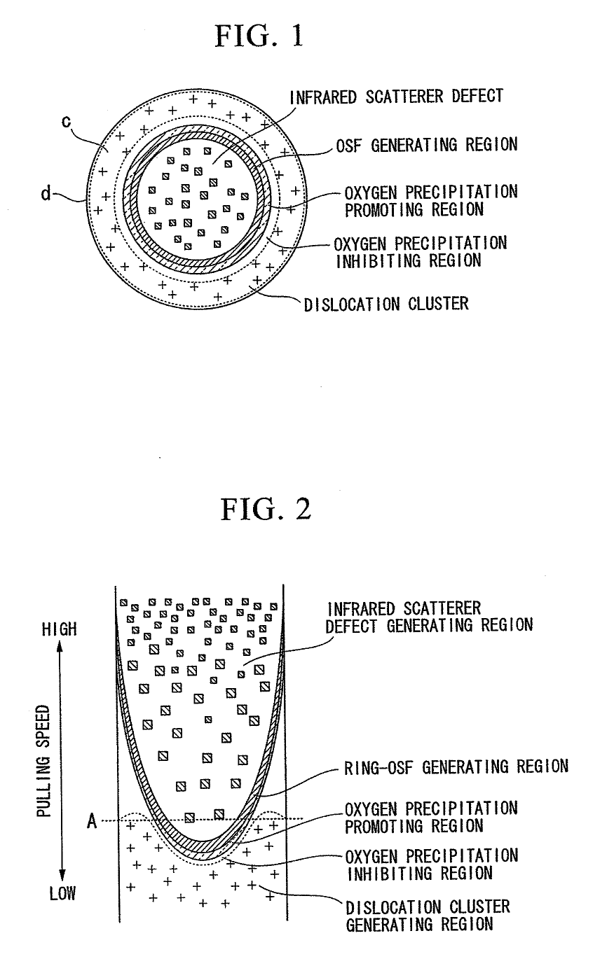

It is known that in a silicon single crystal manufactured by the CZ method, minute defects that are exhibited during a device manufacturing process, that is, grown-in defects occur. FIG. 1 is a cross-sectional view for explaining a defect distribution state of the silicon single crystal obtained by the CZ method in the radial direction. As shown in FIG. 1, the grown-in defects of the silicon single crystal obtained by the CZ method include infrared scatterer defects or vacancy defects called COP (Crystal Originated Particle) or the like which have sizes of 0.1 to 0.2 and minute dislocations called dislocation clusters which have sizes of about 10 μm.

In addition, in the silicon single crystal shown in FIG. 1, a ring-shaped Oxygen induced Stacking Fault (hereinafter, referred to as OSF) is formed in a region corresponding to about ⅔ of the outside diameter of the silicon single crystal. In the portion further in than the OSF generating region where OSF occurs, there is a region (infrared scatterer defect generating region) where about 10⁵ to 10⁶ pieces/cm³ of infrared scatterer defects are detected, and in the portion further out than the OSF generating region, there is a region (dislocation cluster generating region) where about 10³ to 10⁴ pieces/cm³ of dislocation clusters exist.

FIG. 2 is a diagram for explaining a defect distribution state of the cross-section of a silicon single crystal grown by slowly reducing the pulling speed upon pulling. In addition, FIG. 1 is a cross-sectional view of the silicon single crystal grown in the radial direction at a pulling speed corresponding to the position A of FIG. 2.

As shown in FIG. 2, at a stage with a fast pulling speed, a ring OSF generating region is exhibited in a peripheral portion of the crystal, and the portion of the crystal further in than the OSF generating region is an infrared scatterer defect generating region where a number of infrared scatterer defects occur. In addition, as the pulling speed is reduced, the diameter of the OSF generating region is gradually decreased, and a dislocation cluster generating region where a dislocation cluster occurs is exhibited in the portion further out than the OSF generating region. Then, the OSF generating ends, and the dislocation cluster generating region is exhibited over the entire surface.

In the portion contacting the ring OSF generating region on the outer side, there is an oxygen precipitation promoting region (PV region) capable of forming an oxygen precipitate (BMD: Bulk Micro Defect). In addition, there is an oxygen precipitation inhibiting region (PI region) which does not cause an oxygen precipitate between the oxygen precipitation promoting region and the dislocation cluster generating region. The oxygen precipitation promoting region (PV region), the oxygen precipitation inhibiting region (PI region), and the ring OSF generating region are defect-free regions rarely having grown-in defects.

As compared with a silicon single crystal where a dislocation cluster is detected, a silicon single crystal where an infrared scatterer defect is detected does not have a large adverse effect on a device and can be pulled at a high pulling speed, so that the manufacturability thereof is excellent. However, as a reduction in size of an integrated circuit has been required in recent years, a degradation in gate oxide integrity due to the infrared scatterer defect has been pointed out.

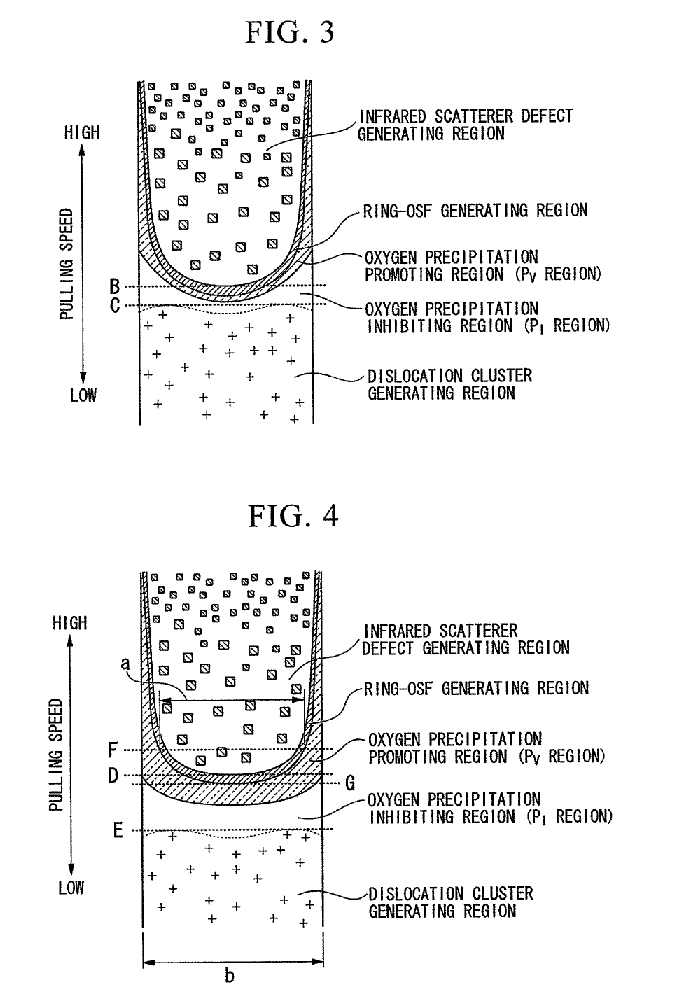

In addition, as a hot zone structure in the case of silicon single crystal growth using the CZ method, for example, there is proposed a hot zone structure (for example, refer to JP-A-2007-22863) in which the temperature gradient (Gc) at the center portion of the crystal is equal to or greater than the temperature gradient (Ge) at the peripheral portion of the crystal (Gc≧Ge). FIG. 3 is a diagram for explaining a defect distribution state of a cross-section of a silicon single crystal. Specifically, FIG. 3 is a cross-sectional view of a silicon single crystal grown by using a growth apparatus having a hot zone structure in which the temperature gradient (Gc) at the center portion of the crystal is equal to or greater than the temperature gradient (Ge) at the peripheral portion of the crystal (Gc≧Ge) and slowly reducing the pulling speed upon pulling of the silicon single crystal.

As shown in FIG. 3, when the growth apparatus having the hot zone structure accomplishing (Gc≧Ge) performs growth at a pulling speed in the range of B to C shown in FIG. 3, a silicon single crystal which has a controlled temperature gradient G on the crystal side in the vicinity of a solid-liquid interface and a uniform defect-free region over the entire wafer surface is obtained.

FIG. 4 is a diagram for explaining a defect distribution state of the cross-section of a silicon single crystal as in FIG. 3. Specifically, FIG. 4 is a cross-sectional view of a silicon single crystal grown by using the growth apparatus having a hot zone structure where Gc≧Ge, supplying an inert gas containing hydrogen to a pulling furnace, and slowly reducing the pulling speed at the time of pulling.

As described above, it is possible to increase a pulling speed margin of defect-free crystal by adding hydrogen to the pulling furnace.

In the case where the atmospheric gas for growing a single crystal is a mixed gas of an inert gas and hydrogen, the pulling speed at the time of ending the OSF generating region at the center portion of the crystal is increased. Therefore, as compared with the case shown in FIG. 3 in which hydrogen is not added to the pulling furnace, in the case shown in FIG. 4 in which hydrogen is added to the pulling surface, a high threshold speed of the pulling speed range (which is a range from B to C in FIG. 3, and a range from D to E in FIG. 4) in which a defect-free crystal can be pulled is allowed.

It is possible to suppress the generation of COP that is an infrared scatterer defect at a pulling speed equal to or lower than the threshold pulling speed at which an OSF generating region occurs by adding hydrogen to the pulling furnace without decreasing the pulling speed of the single crystal. In the case where a silicon single crystal is grown at a pulling speed equal to or higher than the threshold pulling speed at which the OSF generating region occurs, there may be a case where a large cavity made of hydrogen defects occurs. The hydrogen defect is not eliminated by a heat treatment, so that a silicon single crystal having the hydrogen defects cannot be used for a silicon wafer for a semiconductor.

As described above, it is possible to allow a vacancy distribution level in the COP region inside the OSF ring to be equal to or lower than a threshold value at which hydrogen defects occur by allowing the position at which the OSF ring is generated to be equal to or lower than 0.77 with respect to the outside diameter of the silicon single crystal. Therefore, even when the atmospheric gas for growing a single crystal contains a gas of a hydrogen-containing material (a hydrogen containing gas), it is possible to grow a silicon single crystal without hydrogen defects including an OSF generating region.

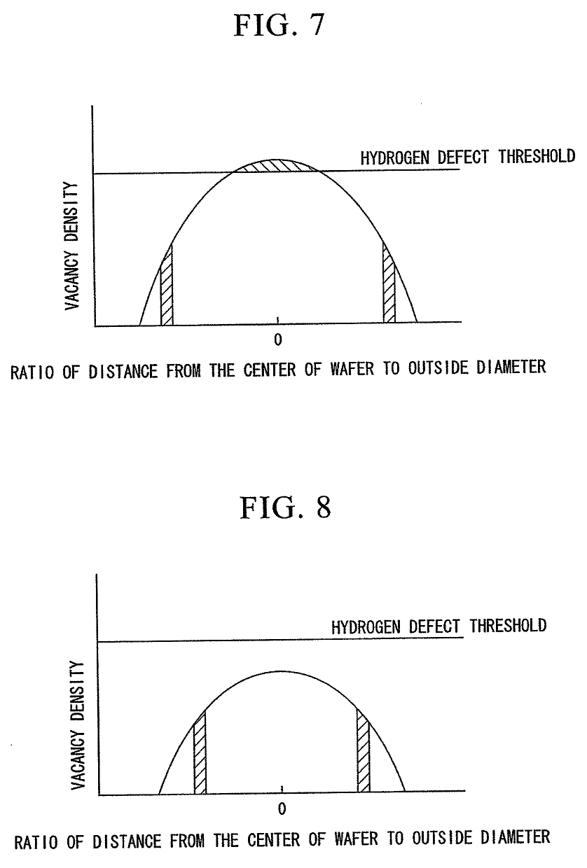

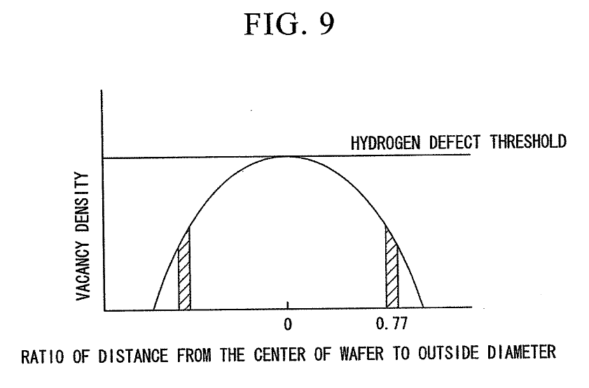

Here, as shown in FIGS. 7 to 9, it is thought that in the COP region inside the OSF ring, the vacancy distribution is highest at the central axis position of the crystal, decreases toward the peripheral direction of the crystal, and is lowest on the immediate inside of the OSF ring. The vacancy distribution state does not depend on a positional change of the OSF ring in the radial direction of the crystal. The vacancy density maintains the distribution in which it is highest at the center axis position of the crystal, decreases toward a peripheral direction of the crystal, and is lowest on the immediate inside of the OSF ring. In addition, as shown in FIGS. 7 to 9, the vacancy concentration at the position in the radial direction corresponding to the OSF ring does not depend on the position in the radial direction which is shown as a hatched portion and at which the OSF ring occurs and has a predetermined value specified by conditions such as a pulling atmosphere. Therefore, as the position of the OSF ring in the radial direction is changed from the outside to the inside, as shown in FIGS. 7, 8, and 9, the vacancy distribution at the center portion of the crystal decreases.

In addition, the hydrogen defect is formed by the agglutination of vacancies, however, it is thought that a certain threshold value is needed for the formation, and in the case where the vacancy density is smaller than a predetermined density, the formation does not occur. Accordingly, in the case where the OSF ring is formed on the outside of the radial direction of the crystal, as shown in FIG. 7, the vacancy density in the COP region inside the OSF ring is high and exceeds a hydrogen defect threshold value, and as a result, there is a high possibility that hydrogen defects will occur. In addition, in the case where the OSF ring is formed on the inside of the radial direction of the crystal, as shown in FIG. 8, the vacancy density in the COP region inside of the OSF ring is low and does not exceed the hydrogen defect threshold value, and as a result, there is a very low possibility that hydrogen defects will occur.

In consideration of those circumstances, the inventors have found that when the OSF ring is at a radial position at which the ratio thereof to the outside diameter of the crystal in the radial direction is about ¾, and more specifically, at which the ratio is equal to or lower than 0.77, the vacancy density in the COP region inside the OSF ring is low and does not exceed the hydrogen defect generation threshold value, and as a result, the possibility of the generation of hydrogen defect is very low. Therefore, the V/G value (V: pulling speed, G: temperature gradient) is set so that the generation position of the OSF ring is on the inner side of a radial position at which the ratio thereof to the outside diameter in the radial direction of the crystal is about ¾, and more specifically, is equal to or lower than 0.77. Under this condition, it is possible to suppress the vacancy density in the COP region inside the OSF ring so as to be low and not to exceed the hydrogen defect generation threshold value, thereby enabling pulling of a silicon single crystal without hydrogen defects.

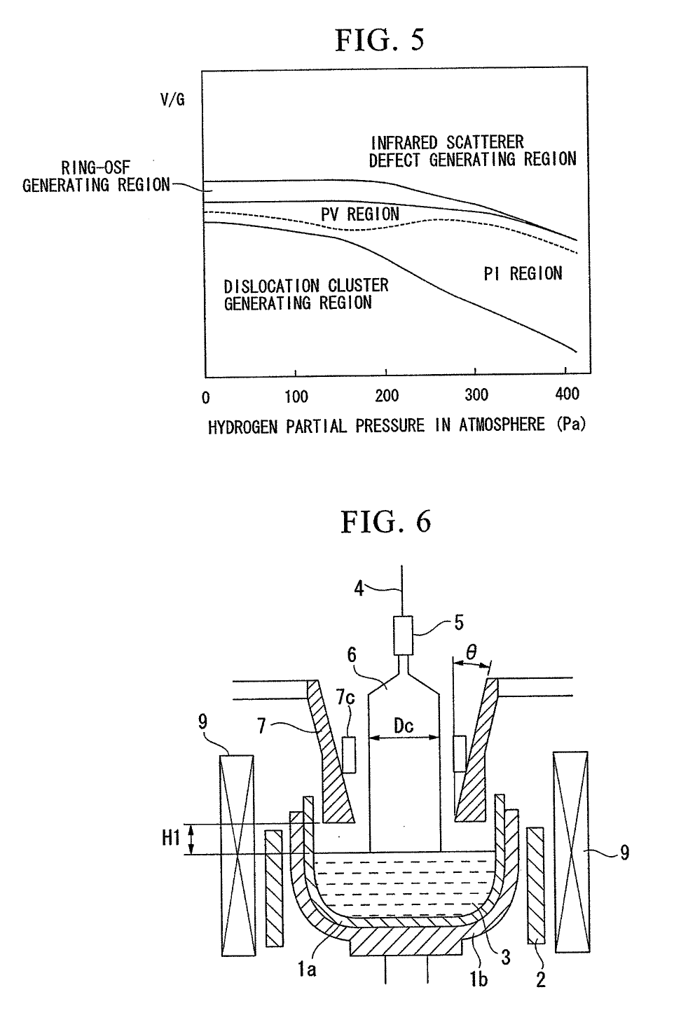

In addition, as shown in FIG. 5, as the pulling is performed in a hydrogen-containing atmosphere, it is possible to decrease the thickness (the thickness in the radial direction of the ring) of the OSF ring and reduce the effect from OSF as compared with the case of a pulling atmosphere without hydrogen. In addition, according to the present invention, although the atmospheric gas for growing a single crystal contains a gas of a hydrogen atom-containing material, a silicon single crystal can be pulled at a pulling speed equal to or higher than a threshold pulling speed at which the OSF generating region occurs so as to be grown. Therefore, it is possible to grow a silicon single crystal at a pulling speed faster than that in the prior art. As described above, since it is possible to pull a single crystal without hydrogen defects and having a reduced effect of the OSF ring at a high speed, as a result, it is possible to reduce the time needed to manufacture a silicon single crystal and silicon wafers, and to reduce manufacturing costs.

On the premise of the above-mentioned circumstances, in the case where a silicon single crystal is practically pulled in a hydrogen atmosphere, although a pulling condition is precisely controlled, each parameter such as temperature is not constant but variable. Therefore, although the parameter itself is in a control target area, there may be a case where the parameter at least temporarily enters a parameter area that causes a single crystal state to generate hydrogen defects, that is, a case where hydrogen defects at least partially occur.

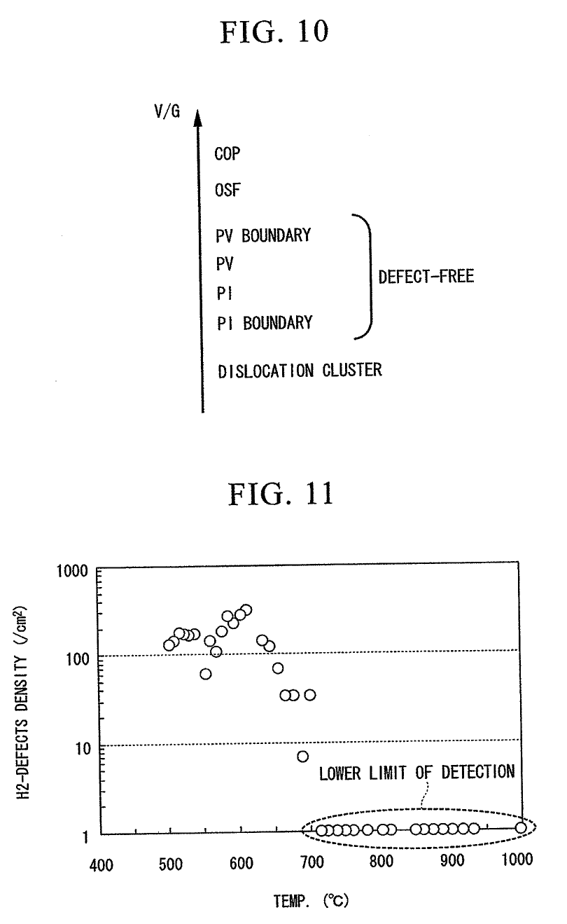

In FIG. 10, in descending order of V/G, a COP generating region, an OSF region, a defect-free region, and a dislocation cluster generating region are shown. In the defect-free region, a PV boundary region where hydrogen defects are likely to occur exists on the side of the OSF region, and a PI boundary region where hydrogen defects are likely to occur exists on the side of the dislocation cluster region. The PV boundary region and the PI boundary region (hereinafter, collectively called a boundary region) have properties to be classified as the defect-free region in appearance, however, have a possibility to generate hydrogen defects when pulling is performed in a hydrogen-containing atmosphere. That is, in the defect-free region, the COP and the dislocation cluster generated in the boundary region may be considered as defect-free, however, minute COP and a generation nucleus of a dislocation cluster exist, and a region where the generation of hydrogen defects from the nucleus is expected exists.

Even in the case where the pulling speed V is maintained in an acceptable range that is increased due to the hydrogen-containing atmosphere and a single crystal is pulled in a state where the temperature gradient G in the crystal radial direction is preferable as shown in FIG. 4, there is a possibility of the generation of the above-mentioned boundary region. In addition, there is a possibility that hydrogen defects will occur in the boundary region.

According to the present invention, in order to prevent the PV boundary region on the side of the OSF region among the boundary regions from being included in the straight portion of the single crystal, the pulling speed may be controlled during the crystal growth process. Specifically, it enables pulling of the silicon single crystal in a range from a pulling speed at which the ratio (a/b) of the outside diameter (a) of a ring composed of an OSF generating region in the radial direction of the silicon single crystal to the diameter (b) of the silicon single crystal is equal to or lower than 0.55 to a pulling speed at which the OSF generating ends at the center portion of the crystal. In addition, it is more preferable that the ratio a/b be equal to or lower than 0.4.

Here, according to the present invention, it is possible to pull the silicon single crystal in which the region outside the ring is a defect-free region.

In addition, in order to prevent the PI boundary region on the side of the dislocation cluster generating region among the boundary regions from being included in the straight portion of the single crystal, the pulling speed may be controlled during the crystal growth process. Specifically, it may enable pulling of the silicon single crystal in a range from a pulling speed at which, in the cross-section of the silicon single crystal in the radial direction, the ratio (c/d) of a wafer area (c) of the silicon single crystal composed of the dislocation cluster generating region to the area (d) of the silicon single crystal is equal to or lower than 0.15 to a pulling speed at which the dislocation cluster generating region is excluded from the entire wafer surface. In addition, it is more preferable that the ratio c/d be equal to or lower than 0.125.

Moreover, according to the present invention, a method of pulling the silicon single crystal in which a region inside the dislocation cluster generating region is a defect-free region may be employed.

In addition, according to the present invention, as described later, an effect in reducing the average size of COP can be sufficiently obtained. Therefore, by performing a heat treatment for forming a defect-free layer on a silicon wafer obtained from the grown silicon single crystal, a silicon wafer which is defect-free and has excellent gate oxide integrity can be obtained. Moreover, according to the present invention, although air leaks and flows into the growth apparatus for growing a silicon single crystal, it is possible safely to perform the operations without burning.

Furthermore, according to the present invention, as described later, it is possible to exclude the dislocation cluster generating region from the grown silicon single crystal, so that an excellent silicon single crystal which does not have an adverse effect on a device due to the dislocation cluster can be grown.

The principle of pulling using hydrogen doping will now be described.

In the apparatus that performs single crystal growth, hydrogen proportionate to the hydrogen partial pressure contained in an inert gas atmosphere is incorporated into a silicon melt and distributed into a solidifying silicon single crystal. The hydrogen concentration in the silicon melt is determined depending on the hydrogen partial pressure in a gas phase according to Henry's law and expressed as:

P_{H2}kC_{LH2}

where P_{H2} is hydrogen partial pressure in the atmosphere, C_{LH2} is the concentration of hydrogen in the silicon melt, and k is the coefficient between the two.

In addition, the concentration of hydrogen in the silicon single crystal is determined by a relationship between the concentration of hydrogen in the silicon melt and a segregation and expressed as:

C_{SH2}=k′C_{LH2}=(k′/k)P_{H2}.

where C_{SH2} is the concentration of hydrogen in the crystal, and k′ is a segregation coefficient of hydrogen between the silicon melt and the crystal.

In this way, when growth of the silicon single crystal is performed in the inert gas atmosphere containing hydrogen, the concentration of hydrogen in the silicon single crystal immediately after solidification is constantly controlled to be a desired concentration in the axial direction of the crystal by controlling the hydrogen partial pressure in the atmosphere. The hydrogen partial pressure may be controlled by the concentration of hydrogen and the pressure in the furnace.

In addition, most of hydrogen that has an effect on the formation of grown-in defects dissipates from the silicon single crystal during a subsequent cooling process.

In order to examine a relationship between the hydrogen partial pressure molecules in the gas of the hydrogen atom-containing material in the atmospheric gas and COP, the growth apparatus having the hot zone structure accomplishing (Gc≧Ge) as in FIG. 3 was used. A silicon single crystal was grown in which a ring composed of an OSF generating region exists in the outermost portion of the silicon single crystal by supplying an inert gas to which hydrogen is added to a pulling furnace to obtain partial pressures of hydrogen molecules of Experimental Examples 1 to 5 shown in Table 1. The average size and density of COP in a silicon wafer acquired from the grown silicon single crystal was obtained.

The results are shown in Table 1. The average size of COP shown in Table 1 was obtained by comparing COP volumes using a defect evaluation apparatus (an Optical Precipitate Profiler (OPP) manufactured by High Yield Technology, Inc.) using infrared interferometry. In addition, the density of COP was calculated on the basis of the number of COPs measured by using an apparatus (MO601 manufactured by Mitsui Mining & Smelting Co., Ltd.) for measuring defects on the surface using light scattering.

TABLE 1

| Experimental | H₂ partial | Defect average | Defect density |
|---|---|---|---|
| example | pressure (Pa) | size (μm) | (/cm²) |
| 1 | No doping | 0.198 | 19.45 |
| 2 | 30 | 0.187 | 24.03 |
| 3 | 40 | 0.105 | 65.24 |
| 4 | 240 | 0.083 | 83.66 |
| 5 | 400 | 0.071 | 92.31 |

As shown in Table 1, as the hydrogen partial pressure molecules increases, the density of COP is increased, and the average size of COP is decreased. When the hydrogen partial pressure molecules is less than 40 Pa, the average size of COP exceeds 0.11 μm, and an effect of reducing the average size of COP cannot be sufficiently obtained, which is not preferable. When the average size of COP is equal to or greater than 0.11 μm, there may be a case where a defect-free silicon wafer cannot be obtained although a heat treatment for forming a defect-free layer on a silicon wafer acquired from the grown silicon single crystal is performed, so that there is a concern that excellent gate oxide integrity cannot be obtained. In addition, as the hydrogen partial pressure molecules of the hydrogen atom-containing material in the atmospheric gas is controlled to be equal to or lower than 400 Pa, even though air leaks and flows into the growth apparatus for growing a silicon single crystal, it is possible to safely perform the operations without burning.

In the method for growing a silicon single crystal according to the present invention, a silicon single crystal which may basically include an OSF generating region and in which the average particle size of COP is smaller than 0.11 μm can be grown. In addition, in the silicon single crystal cooling process, it is possible to grow a silicon single crystal capable of preventing the generation of hydrogen defects even in the boundary regions by allowing an elapsed time in the hydrogen aggregation temperature range to be in the above-mentioned range. A heat treatment for forming a defect-free layer, which is, for example, a heat treatment performed at a temperature equal to or higher than 1100° C. for two or more hours, is performed on a silicon wafer acquired from the grown silicon single crystal. By performing the heat treatment, it is possible to easily form a region on the surface of the silicon wafer where a device is formed, that is, an activating region to be defect-free, so that a silicon wafer having a defect-free layer on its surface can be obtained.

The hydrogen partial pressure contained in the inert gas atmosphere may be adjusted by using a mixed gas of an inert gas and a gas of a hydrogen atom-containing material as the atmospheric gas for growing a single crystal. By adjusting the hydrogen partial pressure, it is possible to adjust pulling speed margins only of the respective regions from among pulling speed margins of a defect-free single crystal.

FIG. 5 is a graph showing a relationship between hydrogen partial pressure in the atmosphere and V/G. A temperature distribution inside a single crystal under pulling in the same hot zone structure hardly changes even when a pulling speed is changed, so that V/G can be regarded as the pulling speed G. As shown in FIG. 5, the pulling speed at which a defect-free crystal is obtained decreases with the increase in hydrogen partial pressure in the atmosphere, however, the pulling speed margin of the defect-free crystal increases.

In addition, the pulling speed margin of the OSF region narrows with the increase in hydrogen partial pressure. The pulling speed margin of the PI region significantly enlarges with the increase in hydrogen partial pressure. The pulling speed margin of the PV region widens or narrows with the increase in hydrogen partial pressure, and more specifically, the pulling speed margin is large at a hydrogen partial pressure of 100 to 250 Pa.

As shown in FIG. 5, by allowing the hydrogen partial pressure of hydrogen containing gas in the atmospheric gas to be equal to or higher than 40 Pa and equal to or lower than 400 Pa, it is possible effectively to increase the pulling speed margin of the defect-free crystal. Accordingly, it is possible to form a silicon single crystal including an OSF generating region grown according to the present invention so as not to allow a dislocation cluster generating region to be mixed and easily divided.

In addition, when the hydrogen partial pressure is set to be lower than 40 Pa, an effect in increasing the pulling speed margin of the defect-free crystal cannot be sufficiently obtained, which is not preferable. In addition, as the hydrogen partial pressure of the gas of a hydrogen atom-containing material in the atmospheric gas is set to be equal to or lower than 400 Pa, even when air leaks and flows into the growth apparatus for growing a silicon single crystal, it is possible to safely perform the operations without burning.

According to the present invention, a silicon single crystal is grown by using the hot zone structure in which the temperature gradient (Gc) at the center portion of the crystal is equal to or greater than the temperature gradient (Ge) at the peripheral portion of the crystal (Gc≧Ge). By using the hot zone structure, it is possible to grow a silicon single crystal in which a region outside a ring composed of an OSF generating region is a defect-free region.

That is, as shown in FIG. 4, the pulling speed is controlled by using the hot zone structure in which the temperature gradient (Gc) at the center portion of the crystal is equal to or greater than the temperature gradient (Ge) at the peripheral portion of the crystal (Gc≧Ge). Specifically, a silicon single crystal is pulled in a pulling speed range (the range of F to G in FIG. 3) of a speed (symbol F in FIG. 4) at which the ratio (a/b) of the outside diameter (a) of the ring composed of the OSF generating region in the radial direction of the silicon single crystal to the diameter (b) of the silicon single crystal is equal to or lower than 0.55 to a speed (symbol G in FIG. 4) at which the OSF generating ends at the center portion of the crystal. Here, areas outside the ring composed of the OSF generating region become a PV region and a PI region. Therefore, there is no situation in which a dislocation cluster generating region is mixed in the silicon single crystal during the growth according to the present invention, and it is possible to grow an excellent silicon single crystal which does not have an adverse effect on a device due to the dislocation cluster.

In addition, by using the hot zone structure described above, the silicon single crystal may be pulled in a range from a pulling speed (pulling speed at a position below symbol E in FIG. 4) at which, in the cross-section of the silicon single crystal in the radial direction, the ratio (c/d) of a wafer area (c) of the silicon single crystal composed of the dislocation cluster generating region to the area (d) of the silicon single crystal is equal to or lower than 0.15 to a pulling speed (pulling speed at a position of symbol E in FIG. 4) at which the dislocation cluster generating region is excluded from the entire wafer surface. In this case, regions other than the dislocation cluster generating region become the PV region and the PI region. Therefore, there is no situation in which a region having COP serving as an excessive void is mixed in the silicon single crystal during the growth according to the present invention, and it is possible to grow an excellent silicon single crystal which does not have an adverse effect on a device due to excessive hydrogen defects.

In addition, as shown in FIG. 4, the effect of G is stronger among the parameter V/G in the boundary between the dislocation cluster generating region and the PI region as compared with the boundary between the OSF generating region and the PV region. Therefore, the pulling speed at which the ratio (c/d) of the wafer area (c) to the area (d) of the silicon single crystal is equal to or lower than 0.15 needs to be proven on the surface of a wafer sliced from the pulled single crystal, so that this is not specified in FIG. 4.

In addition, according to the present invention, in the case where a silicon single crystal including an OSF generating region is grown, or in the case where a silicon single crystal including a dislocation cluster region is grown, the oxygen concentration may be equal to or less than 12×10¹⁷ atoms/cm³ (Old-ASTM).

In addition, even in the case of including the above-mentioned boundary region, it is preferable that the oxygen concentration Oi be in a range of equal to or higher than 1.0×10¹⁷ atoms/cm³ and equal to or lower than 12×10¹⁷ atoms/cm³ (Old-ASTM).

When the oxygen concentration Oi is not in the range of 1.0×10¹⁷ to 12×10¹⁷ atoms/cm³ (Old-ASTM), there is a concern that the characteristics of a silicon wafer acquired from the silicon single crystal deteriorate due to the exhibition of OSF under the condition of the device process. Accordingly, it is preferable that the oxygen concentration be in the above-mentioned range in the method for growing a silicon single crystal of the present invention.

In addition, the adjustment of the oxygen concentration may be performed by adjusting the rotation frequency of a crucible, pressure in a furnace, a heater, and the like. Particularly, in the case where the interstitial oxygen concentration Oi is equal to or lower than 8.5×10¹⁷ atoms/cm³, it is possible to grow a single crystal using an MCZ method for growing a single crystal by applying a magnetic field. In addition, in this case, by reducing the rotation speed of the vitreous silica crucible and a single crystal under pulling, a reduction in the interstitial oxygen concentration can be achieved.

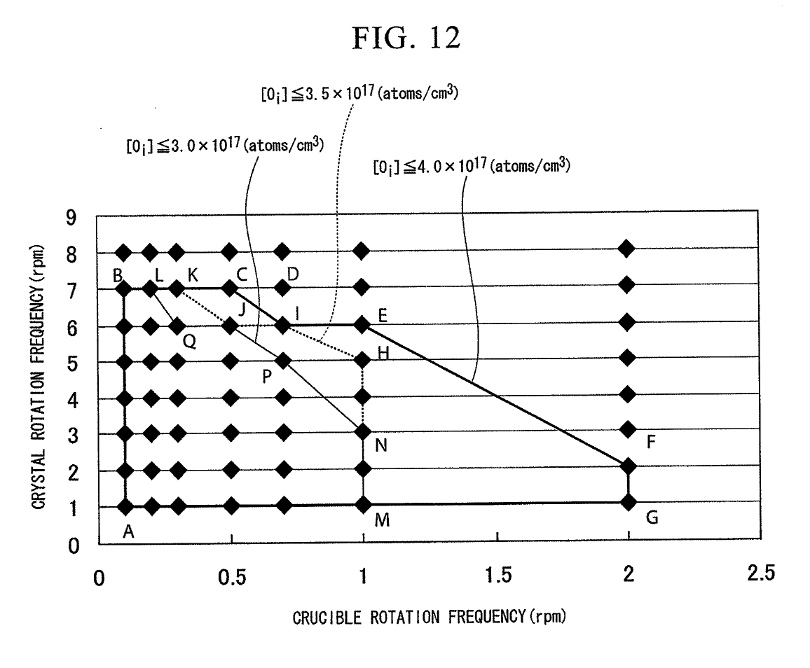

Specifically, as shown in FIG. 12, with regard to a vitreous silica crucible rotation frequency R1 (rpm) and a crystal rotation frequency R2 (rpm), a point (R1, R2) in the figure may be set to have values in the range enclosed by the point A (0.1, 1), the point B (0.1, 7), the point C (0.5, 7), the point D (0.7, 7), the point E (1, 6), the point F (2, 2), and the point G(2, 1). Accordingly, it is possible to grow a single crystal having an interstitial oxygen concentration of equal to or less than 4×10¹⁷ atoms/cm³. Substantially, the rotation frequency of a vitreous silica crucible denoted by R1 (rpm) and the rotation frequency of a silicon single crystal denoted by R2 (rpm) may be set to be in the following ranges: R1 is equal to or higher than 0.1 and equal to or lower than 2; and R2 is equal to or higher than 1 and equal to or lower than 7. Here, in the case where R1 is equal to or higher than 0.5 and equal to or lower than 0.7, R2 may be set to be in the range satisfying R2<7-5(R1-0.5). In the case where R1 is equal to or higher than 0.7 and equal to or lower than 1, R2 may be set to be in the range satisfying R2<6. In the case where R1 is equal to or higher than 1 and equal to or lower than 2, R2 may be set to be in the range satisfying R2<6-4(R1-1). In this case, it is possible to grow a silicon single crystal having a low oxygen concentration by allowing the interstitial oxygen concentration in the single crystal to be equal to or lower than 4.0×10¹⁷ atoms/cm³.

In addition, with regard to the vitreous silica crucible rotation frequency R1 (rpm) and the silicon single crystal rotation frequency R2 (rpm), as shown in FIG. 12, a point (R1, R2) may be set to have values in the range enclosed by the point A (0.1, 1), the point B (0.1, 7), the point L (0.2, 7), the point K (0.3, 7), the point J (0.5, 6), the point I (0.7, 6), the point H (1, 5), the point N (1, 3), and the point M (1, 1) to pull a silicon single crystal. Accordingly, it is possible to grow a single crystal having a low oxygen concentration by allowing the interstitial oxygen concentration in the single crystal to be equal to or lower than 3.5×10¹⁷ atoms/cm³. Substantially, the rotation frequency R1 (rpm) of a vitreous silica crucible and the rotation frequency R2 (rpm) of a silicon single crystal may be set to be in the following ranges: R1 is equal to or higher than 0.1 and equal to or lower than 2; and R2 is equal to or higher than 1 and equal to or lower than 7. Here, in the case where R1 is equal to or higher than 0.3 and equal to or less than 0.5, R2 may be set to be in the range satisfying R2<7-5(R1-0.3). In the case where R1 is equal to or higher than 0.5 and equal to or lower than 0.7, R2 may be set to be in the range satisfying R2<6. In the case where R1 is equal to or higher than 0.7 and equal to or lower than 1, R2 may be set to be in the range satisfying R2<6-3.4(R1-0.7). In this case, it is possible to grow a silicon single crystal having a low oxygen concentration by allowing the interstitial oxygen concentration in the single crystal to be equal to or lower than 3.5×10¹⁷ atoms/cm³.

In addition, with regard to the vitreous silica crucible rotation frequency R1 (rpm) and the silicon single crystal rotation frequency R2 (rpm), as shown in FIG. 12, a point (R1, R2) may be set to have values in the range enclosed by the point A (0.1, 1), the point B (0.1, 7), the point L (0.2, 7), the point Q (0.3, 6), the point J (0.5, 6), the point P (0.7, 5), the point N (1, 3), and the point M (1, 1) to pull a silicon single crystal.

Substantially, the rotation frequency R1 (rpm) of a vitreous silica crucible and the rotation frequency R2 (rpm) of a silicon single crystal may be set to be in the following ranges: R1 is equal to or higher than 0.1 and equal to or lower than 1; and R2 is equal to or higher than 1 and equal to or lower than 7. Here, in the case where R1 is equal to or higher than 0.2 and equal to or lower than 0.3, R2 may be set to be in the range satisfying R2<7-10(R1-0.2). In the case where R1 is equal to or higher than 0.3 and equal to or lower than 0.5, R2 may be set to be in the range satisfying R2<6. In the case where R1 is equal to or higher than 0.5 and equal to or lower than 0.7, R2 may be set to be in the range satisfying R2<6-5(R1-0.5). In the case where R1 is equal to or higher than 0.7 and equal to or lower than 1, R2 may be set to be in the range satisfying R2<5-6.7(R1-0.7). In this case, it is possible to grow a silicon single crystal having a low oxygen concentration by growing a silicon single crystal having an interstitial oxygen concentration in the single crystal of equal to or lower than 3.0×10¹⁷ atoms/cm³.

In addition, even at a low oxygen concentration Oi, hydrogen defects occur. Regardless of the oxygen concentration, hydrogen defects occur. Essentially, it is thought that oxygen does not enter the generated hydrogen defect itself regardless of the oxygen concentration in a mechanism of generating hydrogen defects due to a gas pressure in the above-mentioned void. However, it is thought that the oxygen concentration has an effect when a secondary defect is formed from the hydrogen defect. Therefore, it is possible to achieve a low oxygen concentration as described above.

In addition, according to the present invention, on a silicon wafer acquired from the grown silicon single crystal, as heat treatments such as a donor killer process, DZ, or IG, one or more kinds of heat treatments selected from processes performed in an oxidizing atmosphere, in a non-oxidizing atmosphere, in an inert gas, and in a reducing atmosphere, an RTA heat treatment, a batch type heat treatment, and the like may be suitably combined according to a desired performance of a silicon wafer. The heat treatments may be performed before or after a process of forming an epitaxial layer described later or simultaneously with the process of forming an epitaxial layer.

In addition, the silicon wafer acquired from the silicon single crystal grown according to the present invention is suitable for a substrate on which an epitaxial layer is formed.

As a method of forming an epitaxial layer, a general method may be employed. In this method, an epitaxial silicon wafer without COP marks (infrared scatterer defects) can be obtained even though a thin epitaxial layer having a thickness in the range of 0.5 to 2 μm is formed.

Specifically, on the surface of a 300 mm silicon wafer acquired from the silicon single crystal grown according to the present invention, an epitaxial layer having a thickness of 0.5 μm is formed by using SiHCl₃ gas at a deposition temperature of 1050° C. According to this method, it is possible to reduce the number of epitaxial defects having sizes of equal to or greater than 0.09 μm to be less than 12 on the surface of the silicon wafer.

In the case where the silicon wafer of the present invention includes an OSF region or a dislocation cluster region, the wafer may be used as a test wafer for checking particles or contamination.

In addition, the gas of the hydrogen-containing material may be hydrogen gas.

Here, the hydrogen-containing material is a material which contains hydrogen and is in a gas phase to generate hydrogen gas as it is thermally decomposited when it is dissolved in a silicon melt or introduced to an atmosphere during the formation of a silicon single crystal. The hydrogen-containing material may include hydrogen. It is possible to increase the concentration of hydrogen in the silicon melt by mixing the hydrogen-containing material with an inert gas and introducing the mixed gas to the atmosphere during the growth of a silicon single crystal. Examples of the hydrogen-containing material may include inorganic compounds containing hydrogen atoms such as hydrogen gas, H₂O, and HCl and organic compounds containing silane gas and hydrogen atoms such as hydrocarbons including CH₄, and C₂H₂, alcohol, and carboxylic acid. In addition, examples of the inert gas may include noble gases such as Ar, He, Ne, Kr, and Xe and a mixed gas thereof. As the inert gas (noble gas), generally, argon (Ar) gas is used since it is cheap. However, a mixed gas of Ar gas and other inert gases may be used. As the hydrogen-containing material, one or more kinds of gases are selected from the group consisting of the above gases.

In addition, according to the present invention, the concentration of the hydrogen-containing material in the hydrogen-containing atmosphere is set to allow the reduced hydrogen partial pressure gas to be in the above-mentioned range. Here, the reduced concentration of hydrogen gas is set since an amount of hydrogen gas obtained by thermal decomposition of the hydrogen-containing material depends on reaction efficiency during the thermal decomposition, the number of hydrogen atoms originally contained in the hydrogen-containing material, or the like and varies with respect to the entire amount of the hydrogen-containing material. For example, 1 mole of H₂O contains 1 mole of H₂, however, 1 mole of HCl contains only 0.5 mole of H₂. Therefore, according to the present invention, a hydrogen-containing atmosphere, of which the partial pressure is the above-mentioned the partial pressure (equal to or higher than 40 Pa and equal to or lower than 400 Pa) and which was obtained by introducing hydrogen gas into an inert gas, is regarded as a standard atmosphere. It is preferable that the amount of the hydrogen-containing material to be added be determined by the amount of hydrogen contained in the standard atmosphere in order to obtain the same partial pressure of hydrogen in both places. Therefore, a preferable concentration of the hydrogen-containing material is specified as a reduced concentration of hydrogen gas.

That is, according to the present invention, it is assumed that the hydrogen-containing material is converted into hydrogen gas, and an additional amount of the hydrogen-containing material may be then adjusted to allow the hydrogen partial pressure gas in the atmosphere after the conversion to be in the above-mentioned range.

In addition, in the case where a hydrogen gas is used as the gas of the hydrogen atom-containing material, it may be supplied to a pulling furnace through a dedicated pipe from a commercially available hydrogen gas cylinder, a hydrogen gas storage tank, a hydrogen tank in which a hydrogen occlusion alloy occludes hydrogen, or the like.

In addition, with regard to the concentration of oxygen gas (O₂) in the atmospheric gas, when the reduced concentration of hydrogen molecules in the air of the hydrogen atom-containing material is denoted by α and the concentration of oxygen gas (O₂) is denoted by β, α-2β%3% (volume %) is satisfied. When the concentration β of oxygen gas (O₂) in the atmospheric gas and the reduced concentration a of hydrogen molecules do not satisfy the above-mentioned expression, an effect of suppressing the generation of grown-in defects due to hydrogen atoms incorporated into the silicon single crystal cannot be obtained.

In addition, according to the present invention, in the case where the pressure of a furnace is in the range of equal to or higher than 4 kPa and equal to or lower than 6.7 kPa (30 to 50 Ton), nitrogen (N₂) may exist in the atmospheric gas at a concentration of equal to or lower than 20 volume %.

When the concentration of nitrogen exceeds 20 volume %, an amount of nitrogen dissolved in the silicon melt increases, the concentration of nitrogen in the silicon melt increases due to concentration segregation accompanied by the growth of a silicon single crystal and finally reaches the saturation point. When the concentration of nitrogen reaches its saturation point, a silicon nitride compound precipitates in the silicon melt, and there is concern of a dislocation in the silicon single crystal.

In the method for manufacturing a silicon wafer according to the present invention, as described above, it is possible to pull a silicon single crystal excluding boundary regions from defect-free regions. In addition, in the method for manufacturing a silicon wafer according to the present invention, it is possible to suppress the generation of hydrogen defects even in a single crystal containing boundary regions by using a cooling process. It is possible to allow a silicon wafer acquired from a straight portion of the silicon single crystal grown as described above to have a hydrogen defect density of equal to or less than 0.003 pieces/cm².

In the method for manufacturing a silicon wafer according to the present invention, a method for growing an epitaxial layer on the surface of the silicon wafer, or a method of performing a heat treatment for forming a defect-free layer on the silicon wafer may be employed.

According to the present invention, even through the atmospheric gas for growing a single crystal contains the gas of the hydrogen atom-containing material, it is possible to manufacture a more perfect defect-free crystal by suppressing the generation of hydrogen defects while maintaining high controllability of the V/G during the pulling of a single crystal.

An embodiment of a silicon single crystal and a method for growing thereof, and a silicon wafer and a method for manufacturing thereof according to the present invention will be described with reference to the accompanying drawings.

FIG. 6 is a longitudinal cross-sectional view of a CZ furnace suitable for performing the method for growing a silicon single crystal according to this embodiment.

According to this embodiment, as shown in FIG. 6, a CZ furnace includes a crucible 1 disposed at the center portion of a chamber, a heater 2 disposed on the outside of the crucible 1, and a magnetic field supplying device 9 disposed on the outside of the heater 2. The crucible 1 has a double structure including a vitreous silica crucible 1a for accommodating a silicon melt 3 therein and a graphite crucible 1b on the outside thereof, and is rotated and elevated by a supporting shaft called a pedestal.

A cylindrical heat shield 7 is provided above the crucible 1. The heat shield 7 has a configuration in which an outer shell is made of graphite and the inner space is filled with graphite felt. The inner surface of the heat shield 7 is configured as a tapered surface such that the inside diameter gradually decreases from the upper end to the lower end. The outer surface of the upper portion of the heat shield 7 is a tapered surface corresponding to the inner surface, and the outer surface of the lower portion thereof is configured as a substantially straight surface such that the thickness of the heat shield 7 gradually increases in the downward direction.

The CZ furnace has the hot zone structure in which a temperature gradient (Gc) at the center portion of a crystal is equal to or greater than a temperature gradient (Ge) at the peripheral portion of the crystal (Gc≧Ge).

The heat shield 7 blocks thermal radiation from the heater 2 and the surface of the silicon melt 3 to the side surface of the silicon single crystal 6, surrounds the side surface of the silicon single crystal 6 during the growth, and surrounds the surface of the silicon melt 3. Examples of the specification of the heat shield 7 may include a width W in a radial direction of, for example, 50 mm, a gradient 0 of the inner surface which is a truncated surface with respect to a vertical direction of, for example, 21°, and a height H1 of the lower end of the heat shield 7 from the melt surface of, for example, 60 mm.

In addition, on the inner surface of the heat shield 7, a cooling unit for cooling the side portion of the silicon single crystal 6 during growth is provided. The cooling unit is configured to set the amount of time in a hydrogen aggregation temperature range which is a range of equal to or lower than 850° C. and equal to or higher than 550° C. to be equal to or longer than 100 minutes and equal to or shorter than 480 minutes, when the pulled silicon single crystal is cooled in a cooling state control step described later.

Specifically, on the inside of the heat shield 7, particularly, a water cooling device 7c including a water passing tube with a shape of a coil made of copper or the like, a water cooling jacket having a water passing barrier made of iron or the like, and the like is provided along the inner portion thereof in a height range where the silicon single crystal 6 pulled from the silicon melt 3 is cooled at a temperature equal to or lower than 850° C. and equal to or higher than 550° C. The water cooling device 7c may be configured to rotate a plurality of times in the height range.

In addition, with regard to the strength of a magnetic field supplied from the magnetic field supplying device 9, the strength of a horizontal magnetic field (transverse magnetic field) is equal to or higher than 2000 G and equal to or lower than 4000 G, and more preferably, is equal to or higher than 2500 G and equal to or lower than 3500 G. The center height of the magnetic field is set to be in the range of −150 to +100 mm with respect to the melt surface level (0 mm), and more preferably, in the range of −75 to +50 mm.

In addition, in the case of a cusp magnetic field, the strength of the magnetic field supplied from the magnetic field supplying device 9 is equal to or higher than 200 G and equal to or lower than 1000 G, and more preferably, is equal to or higher than 300 G and equal to or lower than 700 G. The center height of the magnetic field is set to be in the range of −100 to +100 mm with respect to the melt surface level (0 mm), and more preferably, in the range of −50 to +50 mm.

The magnetic field is supplied from the magnetic field supplying device 9 at the above-mentioned magnetic field strength and in the magnetic field center height range, thereby suppressing convection. Accordingly, a desired shape of a solid-liquid interface can be obtained.

Next, a method for growing a silicon single crystal 6 using the CZ furnace according to the embodiment and using a mixed gas of an inert gas and a hydrogen gas as an atmospheric gas for growing silicon single crystal will be described.

### Setting of Operational Condition

First, operational conditions are set. The operational conditions are conditions such as an acceptable range from a pulling speed at which the ratio (a/b) of the outside diameter (a) of a ring composed of an OSF generating region in a radial direction of the silicon single crystal to the diameter (b) of the silicon single crystal is equal to or lower than 0.55 to a pulling speed at which the OSF generating ends at the center portion of the crystal, and an acceptable range from a pulling speed at which, in the cross-section of the silicon single crystal in the radial direction, the ratio (c/d) of a wafer area (c) of the silicon single crystal composed of a dislocation cluster generating region to the area (d) of the silicon single crystal is equal to or lower than 0.15 to a pulling speed at which the dislocation cluster generating region is excluded from the entire wafer surface. In order to examine the conditions, the mixing ratio is set so that the hydrogen partial pressure molecules of the atmospheric gas is 0, 20, 40, 160, 240, and 400 Pa, and under each condition, a silicon single crystal having a target diameter of, for example, 300 mm is grown.

Specifically, for example, 300 Kg of high-purity polysilicon is put into a crucible, and a p-type (B, Al, Ga, and the like) or n-type (P, As, Sb, and the like) dopant is added to allow the electrical resistivity of a silicon single crystal to be a desired value, for example, 10 Ωcm. Then, the pressure on the apparatus is reduced to 1.33 to 26.7 kPa (10 Torr to 200 Torr.) in an argon atmosphere. In addition, the hydrogen partial pressure molecules in the atmospheric gas are set to achieve the predetermined mixing ratio, and the gas is introduced into the surface.

Next, a horizontal magnetic field of, for example, 3000 G is supplied from the magnetic field supplying device 9 to allow the magnetic field center height to be equal to or larger than −75 mm and equal to or smaller than +50 mm with respect to the melt surface level (0 mm). Simultaneously, the polysilicon is heated by the heater 2 to be converted into a silicon melt 3, and a seed crystal attached to a seed chuck 5 is dipped into the silicon melt 3 to pull a silicon single crystal while rotating the crucible 1 and a pulling shaft 4. Here, the rotation frequency of the crucible, the pressure in the furnace, the heater, and the like are adjusted to obtain a desired oxygen concentration of the silicon single crystal. A crystal orientation is one of {100}, {111}, and {110}, seed narrowing is performed to obtain a crystal without a dislocation, a shoulder portion is formed, and the shoulder is changed to achieve a target body diameter.

Next, at the time when the length of the body portion (straight portion) reaches, for example, 300 mm, the pulling speed is adjusted to a level sufficiently higher than a threshold speed, for example, 1.0 mm/min. Thereafter, the pulling speed is reduced substantially straightly according to the pulling length, and when the body length reaches, for example, 600 mm, the pulling speed is set to be lower than the threshold speed, for example, 0.3 mm/min. Then, the body portion is grown to, for example, 1800 mm at this pulling speed, tail narrowing is performed under a typical condition, and the crystal growth is terminated.

The single crystals grown to have different hydrogen concentration as described above are split vertically along the pulling axis, plate-shaped specimens including the vicinity of the pulling axis are manufactured, and Cu decoration is performed to observe the distribution of grown-in defects. First, each specimen is immersed into a cupric sulfate solution and is allowed to dry naturally, and a heat treatment is performed thereon at 900° C. in a nitrogen atmosphere for 20 minutes. Thereafter, in order to remove a Cu silicide layer on the surface of the specimen, it is immersed into a mixed solution of HF/HNO₃, and etching is performed to remove the surface by tens of microns. Thereafter, the position of an OSF ring and the distribution of each defect region are inspected by X-ray topography. In addition, the density of COP in the slice specimen is inspected by, for example, an OPP method, and the density of a dislocation cluster is inspected by, for example, a Secco etching method.

By performing the pulling experiments described above, a relationship between the V/G value of each defect region such as an infrared scatterer defect generating region, an OSF generating region, a PV region, a PI region, and a dislocation cluster generating region, and the hydrogen concentration can be shown. In addition, changing the position at which the pulling speed is changed, from 300 to 600 mm, from 500 to 800 mm, and from 700 to 1000 mm is performed on different portions of a number of crystals. Accordingly, a relationship between the acceptable range of pulling speed (pulling speed margin) which is from a pulling speed at which the ratio (a/b) of the outside diameter (a) of a ring composed of an OSF generating region in a radial direction of the silicon single crystal to the diameter (b) of the silicon single crystal is equal to or lower than 0.55 to a pulling speed at which the OSF generating ends at the center portion of the crystal, and the position in the crystal axial direction is shown, so that it is possible to set the operational condition. Otherwise, a relationship between the acceptable range of pulling speed (pulling speed margin) which is from a pulling speed at which, in the cross-section of the silicon single crystal in the radial direction, the ratio (c/d) of a wafer area (c) of the silicon single crystal composed of a dislocation cluster generating region to the area (d) of the silicon single crystal is equal to or lower than 0.15 to a pulling speed at which the dislocation cluster generating region is excluded from the entire wafer surface, and the position in the crystal axial direction is shown, so that it is possible to set the operational conditions.

### Growth of Silicon Single Crystal

Next, growth of a silicon single crystal 6 is performed by using the CZ furnace shown in FIG. 6 and using the mixed gas of an inert gas and a hydrogen gas as the atmospheric gas for growing a single crystal under the operational condition set by the above-mentioned method.

Here, in the crystal growth process, the atmospheric gas contains a gas of a hydrogen-containing material so as to allow the reduced hydrogen partial pressure gas to be equal to or higher than 40 Pa and equal to lower than 400 Pa. In addition, the silicon single crystal pulled in the crystal growth process is cooled. In a cooling state control process, by using the water cooling device or the like, the amount of time in a hydrogen aggregation temperature range which is a range where a silicon single crystal is at a temperature equal to or lower than 850° C. and equal to or higher than 550° C. is set to be equal to or longer than 100 minutes and equal to or shorter than 480 minutes.

Here, in the crystal growth process, pulling is performed in a range from a pulling speed at which the ratio (a/b) of the outside diameter (a) of a ring composed of an OSF generating region in a radial direction of the silicon single crystal to the diameter (b) of the silicon single crystal is equal to or lower than 0.55 to a pulling speed at which the OSF generating ends at the center portion of the crystal. In this case, it is possible to pull the silicon single crystal in which a region outside the dislocation cluster generating region is a defect-free region. In addition, in the crystal growth process, pulling is performed in a range from a pulling speed at which, in the cross-section of the silicon single crystal in the radial direction, the ratio (c/d) of a wafer area (c) of the silicon single crystal composed of a dislocation cluster generating region to the area (d) of the silicon single crystal is equal to or lower than 0.15 to a pulling speed at which the dislocation cluster generating region is excluded from the entire wafer surface. In this case, it is possible to pull the silicon single crystal in which a region inside the ring is a defect-free region.

In either case, a temperature gradient (Gc) at the center portion of the crystal is set to be equal to or greater than a temperature gradient (Ge) at the peripheral portion of the crystal (Gc≧Ge) to allow the hydrogen defects density to be equal to or smaller than 0.003 pieces/cm² and to allow the oxygen concentration to be equal to or less than 12×10¹⁷ atoms/cm³ (Old-ASTM).

After the silicon single crystal is grown by the abovementioned process, the silicon single crystal is sliced by a cutting device such as an ID saw or a wire saw using a typical processing method and processed through chamfering, wrapping, etching, grinding, and the like into silicon single crystal wafers. In addition, the method for manufacturing the wafers includes various processes such as cleaning in addition to the above-mentioned processes, the order the process are done can be changed such as omitted or modified depending on the purpose.

On the wafers obtained as described above, an RTA (Rapid Thermal Annealing) process for performing a heat treatment may be performed at a temperature of equal to or higher than 1100° C. and equal to or lower than 1350° C. in an Ar or He atmosphere containing Ar, He, or NH₃ for 0 to tens of seconds. Accordingly, it is possible to obtain an excellent wafer in which a device activating region is completely defect-free without performing a heat treatment for oxygen diffusion at a high temperature for a long time during the formation of a DZ layer. In addition, when the heat treatment temperature is less than 1100° C., there may be a case where the device activating region is not completely defect-free.

In addition, in the embodiment described above, a case where the RTA process is performed on the wafer is described. However, according to the present invention, an epitaxial layer may be performed on the surface of a wafer without an RTA process, or an epitaxial layer may be performed on the surface of a wafer before or after performing the RTA process. By forming an epitaxial layer on the surface of the obtained wafer, it is possible to obtain an epitaxial silicon wafer without COP (infrared scatterer defect) marks.

### EXAMPLES

### Exemplary Embodiment 1

Hereinafter, a hydrogen aggregation temperature range of about 600 to 700° C. is described according to Examples.

In order to examine a temperature range in which hydrogen defects (H₂ defects) are formed during the growth of a hydrogen-doped crystal, a separation rapid cooling experiment was performed. The separation rapid cooling experiment is a technique of forming a straight portion of a single crystal into a predetermined length, stopping pulling of the single crystal for a predetermined time, and separating the single crystal from the melt to measure the size distribution of defects in an axial direction.

As shown in FIG. 6, a single crystal with a predetermined diameter is grown by using CZ furnace, and pulling is stopped at the time when the single crystal reaches a predetermined length. Here, rotation of the crystal pulling shaft and the crucible supporting shaft is continued. After maintaining this state for a predetermined amount of time, the single crystal is drawn and separated from the silicon melt. In addition, in order to maintain a solid-liquid interface state while the pulling is stopped, the temperature of the melt is controlled. It is preferable that cooling using the water cooling device 7c not be used in the separation rapid cooling experiment.

The single crystal grown as described above is in a state maintained at a temperature according to the distance from the solid-liquid interface at the time of stopping the pulling for a predetermined time. In addition, after stopping the pulling, without performing tailing, the single crystal is drawn and separated from the silicon melt, so that the defect state in each temperature range distributed in the single crystal in the axial direction is maintained as it is. Therefore, it is possible to examine the behavior of the defects during the crystal growth. In addition, it is preferable that the single crystal separated from the silicon melt be rapidly cooled as compared with the state during the pulling, and by performing the cooling, the defect state in each temperature region in the single crystal is frozen, and examining the behavior of the defects during the crystal growth becomes easier. The cooling may be natural cooling or forced cooling.

Specifically, in order to emphasize the defect formation temperature during the crystal growth, the partial pressure of H₂ was set to 400 Pa, the crystal growth was stopped while a silicon single crystal with a diameter of 200 mm is grown at a pulling speed of 0.65 mm/min and maintained for 5 hours, and the silicon single crystal was separated from a solid-liquid interface.

Thereafter, the crystal was split vertically along the growth direction and processed, mirror etching using a mixed acid of HF and HNO₄ was performed thereon, Secco etching was performed thereon for 30 minutes, and then H₂ defects were measured. H₂ defects are line-shaped defects in <110> and can be observed by an optical microscope after the Secco etching.

The result is shown in FIG. 11. The X-axis in the figure represents a temperature at which the crystal is maintained for 5 hours during the growth, and the generation of defects that occur during crystallization is more exhibited. H₂ defects are detected from a temperature at which the crystal is maintained at 700° C. and peak at 600° C. In addition, the defects are almost constant in a temperature range of equal to or lower than 550° C. From the result, it could be seen that the temperature range in which H₂ defects occur is a temperature range of equal to or lower than 700° C. and equal to or higher than 600° C.

### Experimental Example 2

Next, the silicon single crystal was pulled in a range from a pulling speed at which the ratio (a/b) of the outside diameter (a) of a ring composed of an OSF generating region in a radial direction of the silicon single crystal to the diameter (b) of the silicon single crystal is equal to or lower than 0.55 to a pulling speed at which the OSF generating ends at the center portion of the crystal, in the CZ furnace shown in FIG. 6, and not in the range. Here, additionally, a crystal was grown by changing the cooling speed in a temperature range of equal to or lower than 800° C. and equal to or higher than 550° C. including a temperature range of equal to or lower than 700° C. and equal to or higher than 600° C.

After the wafer mirror processing, using a laser microscope or a dark-field microscope in a confocal optical system, H₂ defects were measured by an inspection device (manufactured by Lasertec. Co., Ltd, Magics: type M5350) that can inspect defects, minute defects aggregated as a colony and defects of which the total defect size is equal to or greater than 0.5 μm. The result is shown in Table 2.

TABLE 2

| | | | Ratio of | |
|---|---|---|---|---|
| | | | position | Density of |
| | H₂ partial | 800-600° C. | having OSF-ring | H2 defect |
| Sample | pressure (Pa) | stay time (min) | and diameter | (/cm²) |
| Sample 1 | 50 | 807 | 0.51 | 0.019 |
| Sample 2 | 50 | 478 | 0.53 | <0.003 |
| Sample 3 | 50 | 246 | 0.53 | <0.003 |
| Sample 4 | 400 | 807 | 0.52 | 0.14 |
| Sample 5 | 400 | 478 | 0.53 | <0.003 |
| Sample 6 | 400 | 246 | 0.53 | <0.003 |
| Sample 7 | 400 | 246 | 0.6 | 0.016 |

According to the result, it can be seen that H₂ defects were suppressed by controlling the partial pressure of H₂, the stay time in the range of 800 to 600° C., and the ratio of the position having an OSF ring to the diameter.

That is, it can be seen that H₂ defects were suppressed by rapidly cooling the hydrogen aggregation temperature range.

### Experimental Example 3

In the same manner, the silicon single crystal was pulled in a range from a pulling speed at which, in the cross-section of the silicon single crystal in the radial direction, the ratio (c/d) of a wafer area (c) of the silicon single crystal composed of the dislocation cluster generating region to the area (d) of the silicon single crystal is equal to or lower than 0.15 to a pulling speed at which the dislocation cluster generating region is excluded from the entire wafer surface, in the CZ furnace shown in FIG. 6, and not in the range. Here, a crystal was also grown by changing the cooling speed in a temperature range of equal to or lower than 800° C. and equal to or higher than 550° C. including a temperature range of equal to or lower than 700° C. and equal to or higher than 600° C. The result is shown in Table 3.

TABLE 3

| | | | Ratio of | |
|---|---|---|---|---|
| | | | dislocation | Density of |
| | H₂ partial | 800-600° C. | cluster region to | H₂ defect |
| Sample | pressure (Pa) | stay time (min) | area | (/cm²) |
| Sample 8 | 50 | 807 | 0.127 | 0.025 |
| Sample 9 | 50 | 478 | 0.141 | <0.003 |
| Sample 10 | 50 | 246 | 0.138 | <0.003 |
| Sample 11 | 400 | 807 | 0.135 | 0.047 |
| Sample 12 | 400 | 478 | 0.132 | <0.003 |
| Sample 13 | 400 | 246 | 0.148 | <0.003 |
| Sample 14 | 400 | 246 | 0.21 | 0.057 |

According to the result, it can be seen that H₂ defects were suppressed by controlling the partial pressure of H₂, the stay time in the range of 800 to 600° C., and the ratio of the dislocation cluster region to the area.

That is, it can be seen that H₂ defects were suppressed by rapidly cooling the hydrogen aggregation temperature range.

While preferred embodiments of the present invention have been described and shown above, it should be understood that these are exemplary of the present invention and are not to be considered as limiting. Additions, omissions, substitutions, and other modifications can be made without departing from the spirit or scope of the present invention. Accordingly, the present invention is not to be considered as being limited by the foregoing description, and is only limited by the scope of the appended claims.

What is claimed is:

1. A method for growing a silicon single crystal having a hydrogen defect density of equal to or less than 0.003 pieces/cm² using a Czochralski method, comprising:
a crystal growth step of glowing the silicon single crystal in an atmospheric gas containing a hydrogen-containing gas so as to allow the reduced hydrogen partial pressure gas to be equal to or higher than 40 Pa and equal to or lower than 400 Pa; and
a cooling state control step of keeping the silicon single crystal in a hydrogen aggregation temperature range which is a range of equal to or lower than 850° C. and equal to or higher than 550° C. to be equal to or longer than 100 minutes and equal to or shorter than 480 minutes.

2. The method for growing a silicon single crystal according to claim 1, wherein, in the crystal growth step, the silicon single crystal is pulled in a range from a pulling speed at which the ratio (a/b) of the outside diameter (a) of a ring composed of an OSF generating region in a radial direction of the silicon single crystal to the diameter (b) of the silicon single crystal is equal to or lower than 0.55 to a pulling speed at which the OSF generating ends at the center portion of the crystal.

3. The method for growing a silicon single crystal according to claim 2, wherein the silicon single crystal in which an area outside the ring is a defect-free region is pulled.

4. The method for growing a silicon single crystal according to claim 1, wherein, in the crystal growth step, the silicon single crystal is pulled in a range from a pulling speed at which, in the cross-section of the silicon single crystal in the radial direction, the ratio (c/d) of a wafer area (c) of the silicon single crystal composed of a dislocation cluster generating region to the area (d) of the silicon single crystal is equal to or lower than 0.15 to a pulling speed at which the dislocation cluster generating region is excluded from the entire wafer surface.

5. The method for growing a silicon single crystal according to claim 4, wherein the silicon single crystal in which an area inside the dislocation cluster generating region is a defect-free region is pulled.

6. The method for growing a silicon single crystal according to claim 1, wherein the silicon single crystal is grown by using a hot zone structure in which a temperature gradient (Gc) at the center portion of the crystal is equal to or greater than a temperature gradient (Ge) at the peripheral portion of the crystal (Gc≧Ge).

7. The method for growing a silicon single crystal according to claim 1, wherein an oxygen concentration is equal to or less than 12×10¹⁷ atoms/cm³ (Old-ASTM).

8. The method for growing a silicon single crystal according to claim 1, wherein the hydrogen-containing gas is hydrogen gas.

9. A silicon single crystal grown by the method for growing a silicon single crystal according to claim 1.

10. A method for manufacturing a silicon wafer, comprising:
acquiring a silicon wafer from a straight portion of the silicon single crystal according to claim 9,
wherein the silicon wafer has a hydrogen defect density of equal to or less than 0.003 pieces/cm².

11. The method for manufacturing a silicon wafer according to claim 10, further comprising growing an epitaxial layer on the surface of the silicon wafer.

12. The method for manufacturing a silicon wafer according to claim 10, further comprising performing a heat treatment for forming a defect-free layer on the silicon wafer.

13. A silicon wafer manufactured by the manufacturing method according to claim 10.
